(19) United States
(12) Patent Application Publication
(10) Pub. No.: US 2026/0045281 A1
(43) Pub. Date: Feb. 12, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventor: Kwang-Soo Kim, Suwon-si (KR)

(21) Appl. No.: 19/072,721

(22) Filed: Mar. 6, 2025

(30) Foreign Application Priority Data
Aug. 7, 2024 (KR) 10-2024-0105062

(51) Int. Cl. G11C 5/06; G11C 16/04; H01L 23/00; H01L 25/18; H10B 43/10; H10B 43/27; H10B 43/35; H10B 43/40; H10B 51/10; H10B 51/20; H10B 51/40; H10B 80/00; H10D 80/30

(52) U.S. Cl. CPC G11C 5/063; G11C 16/0483; H01L 24/08; H01L 25/18; H10B 43/10; H10B 43/27; H10B 43/35; H10B 43/40; H10B 51/10; H10B 51/20; H10B 51/40; H10B 80/00; H10D 80/30; H01L 24/32; H01L 24/48; H01L 2224/08145; H01L 2224/32145; H01L 2224/32225; H01L 2224/48147; H01L 2224/48227; H01L 2225/06506; H01L 2225/0651; H01L 2225/06524; H01L 2924/1438; H01L 2924/1441

(57) ABSTRACT

A semiconductor memory device includes a peripheral circuit structure and a cell structure stacked on the peripheral circuit structure. The cell structure includes a plurality of gate electrodes stacked and spaced apart from each other in a first direction, first and second channel structures elongated in the first direction and extending through the plurality of gate electrodes and spaced apart from each other. The first and second channel structures each includes a channel layer, and a vertical gate electrode spaced apart from the respective channel layer. The cell structure includes a common source layer connected to the first channel layer and the second channel layer, respectively and also first and second wiring plates connected to the respective vertical gate electrodes and spaced apart from each other. The cell structure includes a wiring isolation pattern disposed between the first wiring plate and the second wiring plate.

### CROSS-REFERENCE TO RELATED APPLICATION

This application claims priority to Korean Patent Application No. 10-2024-0105062, filed in the Korean Intellectual Property Office on Aug. 7, 2024, the entire contents of which are hereby incorporated by reference.

### BACKGROUND

The present disclosure relates to a semiconductor memory device and an electronic system including the same.

There is a need for a semiconductor memory device capable of storing high-capacity data in an electronic system that requires data storage. Accordingly, ways to increase the data storage capacity of the semiconductor memory devices are being studied. For example, as one of the methods for increasing the data storage capacity of the semiconductor memory device, a semiconductor memory device has been proposed, which includes three-dimensional arrangement of memory cells instead of two-dimensional arrangement of memory cells.

### SUMMARY

In order to solve one or more problems (e.g., the problems described above and/or other problems not explicitly described herein), the present disclosure provides a semiconductor memory device with improved electrical characteristics.

In order to solve one or more problems (e.g., the problems described above and/or other problems not explicitly described herein), the present disclosure also provides an electronic system with improved electrical characteristics.

According to some implementations of the present disclosure, by forming the first wiring plate and the second wiring plate disposed in one memory cell block and independently operating the first wiring plate and the second wiring plate, the electrical characteristics of the semiconductor memory device can be improved.

According to some implementations of the present disclosure, a semiconductor memory device may include a peripheral circuit structure, and a cell structure stacked on the peripheral circuit structure, wherein the cell structure includes, a plurality of gate electrodes stacked and spaced apart from each other in a first direction, a first channel structure elongated in the first direction and extending through the plurality of gate electrodes, wherein the first channel structure includes a first channel layer and a first vertical gate electrode spaced apart from the first channel layer, a second channel structure elongated in the first direction and extending through the plurality of gate electrodes, wherein the second channel structure includes a second channel layer and a second vertical gate electrode spaced apart from the second channel layer, a common source layer connected to the first channel layer and the second channel layer, respectively, a first wiring plate connected to the first vertical gate electrode, a second wiring plate connected to the second vertical gate electrode and disposed to be spaced apart from the first wiring plate, and a wiring isolation pattern disposed between the first wiring plate and the second wiring plate.

According to some implementations of the present disclosure, a semiconductor memory device may include a peripheral circuit structure, and a cell structure stacked on the peripheral circuit structure, wherein the cell structure further includes, a plurality of gate electrodes stacked and spaced apart from each other in a first direction, a plurality of mold isolation structures elongated in the first direction and a second direction orthogonal to the first direction and separating the plurality of gate electrodes, a first channel structure elongated in the first direction and extending through the plurality of gate electrodes, wherein the first channel structure includes a first channel layer and a first vertical gate electrode spaced apart from the first channel layer, a second channel structure elongated in the first direction and extending through the plurality of gate electrodes, wherein the second channel structure includes a second channel layer and a second vertical gate electrode spaced apart from the second channel layer, a common source layer connected to the first channel layer and the second channel layer, respectively, an upper insulating layer on the common source layer, a common source contact in the upper insulating layer and connected to the common source layer, a first vertical gate contact extending through the upper insulating layer and the common source layer, wherein the first vertical gate contact is connected to the first vertical gate electrode, a first wiring plate on the upper insulating layer, connected to the first vertical gate contact, and extending in the second direction, a second vertical gate contact extending through the upper insulating layer and the common source layer, wherein the second vertical gate contact is connected to the second vertical gate electrode, a second wiring plate on the upper insulating layer, connected to the second vertical gate contact, and extending in the second direction, and a wiring isolation pattern between the first wiring plate and the second wiring plate.

According to some implementations of the present disclosure, a electronic system may include a main substrate, a semiconductor memory device on the main substrate, which includes a peripheral circuit structure, and a cell structure stacked on the peripheral circuit structure, and a controller on the main substrate, which is electrically connected to the semiconductor memory device, wherein the cell structure includes, a plurality of gate electrodes stacked and spaced apart from each other in a first direction, a first channel structure elongated in the first direction and extending through the plurality of gate electrodes, wherein the first channel structure includes a first channel layer and a first vertical gate electrode spaced apart from the first channel layer, a second channel structure elongated in the first direction and extending through the plurality of gate electrodes, wherein the second channel structure includes a second channel layer and a second vertical gate electrode spaced apart from the second channel layer, a common source layer connected to the first and second channel layers, respectively, and electrically connected to the controller, a first wiring plate connected to the first vertical gate electrode, a second wiring plate connected to the second vertical gate electrode and disposed to be spaced apart from the first wiring plate, and a wiring isolation pattern between the first wiring plate and the second wiring plate.

### BRIEF DESCRIPTION OF THE DRAWINGS

The above and other implementations and features of the present disclosure will become more apparent by describing in detail example implementations thereof with reference to the attached drawings, in which:

FIG. 1 is a block diagram of a semiconductor memory device according to some implementations;

FIG. 2 is a circuit diagram illustrating a memory cell array according to some implementations;

FIG. 3 is a perspective view of a representative configuration of a semiconductor memory device according to some implementations;

FIG. 4 is an example plan view of a semiconductor memory device according to some implementations;

FIG. 5 is a cross-sectional view taken along line A-A of FIG. 4;

FIG. 6 is a cross-sectional view taken along line B-B of FIG. 4;

FIG. 7 is an enlarged view provided to explain a region Q1 of FIG. 6;

FIG. 8 is an enlarged view provided to explain a region Q2 of FIG. 6;

FIGS. 9 and 10 are example layout diagrams of the wiring plate and the wiring isolation pattern of FIG. 6;

FIG. 11 is a diagram provided to explain a semiconductor memory device according to some implementations;

FIGS. 12 and 13 are example layout diagrams of the wiring plate and the wiring isolation pattern of FIG. 11;

FIG. 14 is a diagram provided to explain a semiconductor memory device according to some implementations;

FIGS. 15 and 16 are diagrams provided to explain a semiconductor memory device according to some implementations;

FIGS. 17 to 23 are diagrams illustrating intermediate stages, which are provided to explain a method for manufacturing a semiconductor memory device according to some implementations;

FIG. 24 is an example block diagram provided to explain an electronic system according to some implementations;

FIG. 25 is an example perspective view illustrating an electronic system including a semiconductor memory device according to some implementations;

FIG. 26 is a schematic cross-sectional view taken along line V-V of FIG. 24.

### DETAILED DESCRIPTION

A semiconductor memory device and a method for manufacturing the same according to some implementations of the present disclosure will be described in detail with reference to drawings.

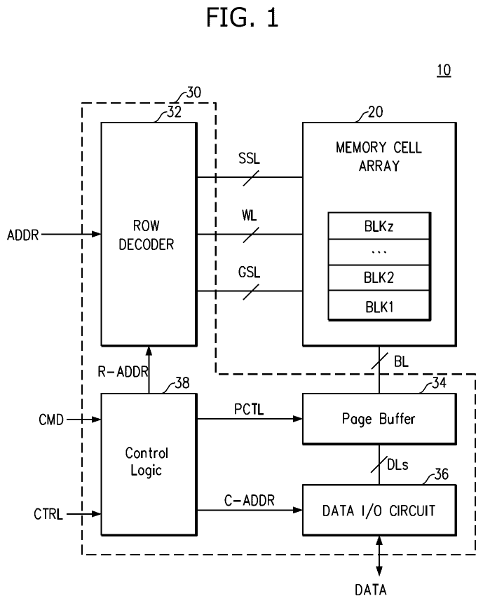

FIG. 1 is a block diagram of a semiconductor memory device according to some implementations.

Referring to FIG. 1, a semiconductor memory device 10 may include a memory cell array 20 and a peripheral circuit 30. The memory cell array 20 includes a plurality of memory cell blocks BLK1, BLK2, . . . , BLKn. Each of the plurality of memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string select line SSL, and a ground select line GSL.

The peripheral circuit 30 may include a row decoder 32, a page buffer 34, a data input and output circuit 36, and a control logic 38. The peripheral circuit 30 may further include an input and output interface, a column logic, a voltage generation unit, a pre-decoder, a temperature sensor, a command decoder, an address decoder, an amplification circuit, etc.

The memory cell array 20 may be connected to the page buffer 34 through the bit line BL and may be connected to the row decoder 32 through the word line WL, the string select line SSL, and the ground select line GSL. In the memory cell array 20, each of the plurality of memory cells included in the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each of the NAND strings may include a plurality of memory cells connected to a plurality of word lines WL vertically stacked on a substrate.

The peripheral circuit 30 may receive an address ADDR, a command CMD, and a control signal CTRL from the outside of the semiconductor memory device 10 and may transmit and receive data DATA to and from an external device outside the semiconductor memory device 10.

The row decoder 32 may select at least one of the plurality of memory cell blocks BLK1, BLK2, . . . , and BLKn in response to the address ADDR from the outside, and may select the word line WL, the string select line SSL, and the ground select line GSL of the selected memory cell block. The row decoder 32 may transfer a voltage for performing the memory operation to the word line WL of the selected memory cell block.

The page buffer 34 may be connected to the memory cell array 20 through the bit lines BL. The page buffer 34 may operate as a write driver during a program operation to apply a voltage according to the data DATA to be stored in the memory cell array 20 to the bit line BL and may operate as a sense amplifier during a read operation to sense the data DATA stored in the memory cell array 20. The page buffer 34 may operate according to a control signal PCTL provided from the control logic 38.

The data input and output circuit 36 may be connected to the page buffer 34 through data lines DL.

The data input and output circuit 36 during the program operation may receive the data DATA from the memory controller and provide the program data DATA to the page buffer 34 based on a column address C_ADDR provided from the control logic 38. The data input and output circuit 36 during the read operation may provide the read data DATA stored in the page buffer 34 to the memory controller based on the column address C_ADDR provided from the control logic 38.

The data input and output circuit 36 may transmit an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide the row address R_ADDR to the row decoder 32 and the column address C_ADDR to the data input and output circuit 36. In response to the control signal CTRL, the control logic 38 may generate various internal control signals for use in the semiconductor memory device 10. For example, when performing a memory operation such as program operation, erase operation, etc., the control logic 38 may adjust the voltage level provided to the word line WL and the bit line BL.

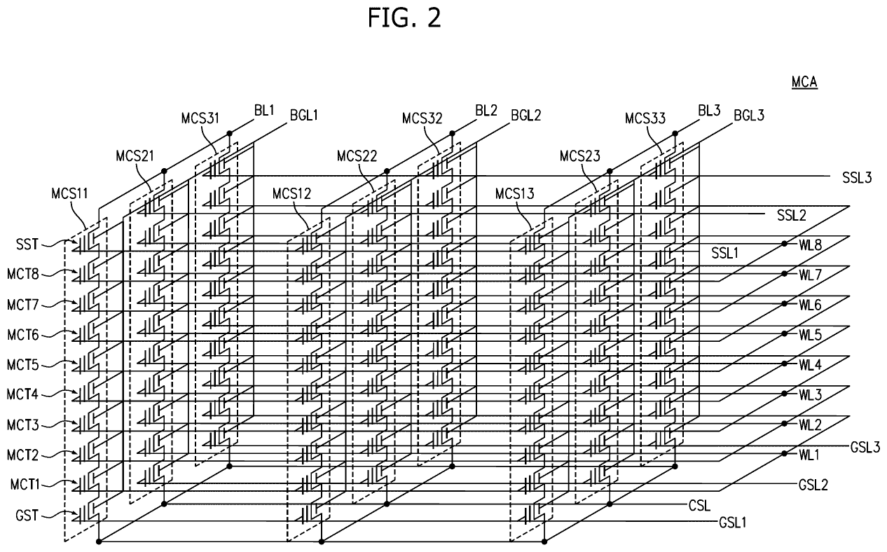

FIG. 2 is a circuit diagram illustrating a memory cell array according to some implementations.

Referring to FIG. 2, a memory cell array MCA may include memory cell strings MCS11 to MCS33, word lines WL1 to WL8, a ground select line GSL, string select lines SSL1 to SSL3, and a common source line CSL.

Memory cell strings MCS11, MCS21, and MCS31 may be provided between a first bit line BL1, a first back gate line BGL1, and a common source line CSL, memory cell strings MCS12, MCS22, and MCS32 may be provided between a second bit line BL2, a second back gate line BGL2, and the common source line CSL, and memory cell strings MCS13, MCS23, and MCS33 may be provided between a third bit line BL3, a third back gate line BGL3, and the common source line CSL. Each of the memory cell strings (e.g., MCS11) may include a string select transistor SST, a plurality of memory cells MCT1 to MCT8, and a ground select transistor GST connected in series.

The string select transistor SST may be connected to the corresponding string select lines SSL1 to SSL3. The plurality of memory cells MCT1 to MCT8 may be connected to the corresponding the word lines WL1 to WL8, respectively. The ground select transistor GST may be connected to corresponding ground select lines GSL1 to GSL3. The string select transistor SST may be connected to the corresponding bit lines BL1 to BL3, and the ground select transistor GST may be connected to the common source line CSL.

The word lines (e.g., WL1) of the same height are commonly connected to each other, the string select lines SSL1 to SSL3 are separated from each other, and the ground select lines GSL1 to GSL3 are also separated from each other. FIG. 2 illustrates that the three string select lines SSL1 to SSL3 share the word lines of the same height, but implementations are not limited thereto. For example, two string select lines may share the word lines of the same height. As another example, four string select lines may share the word lines of the same height.

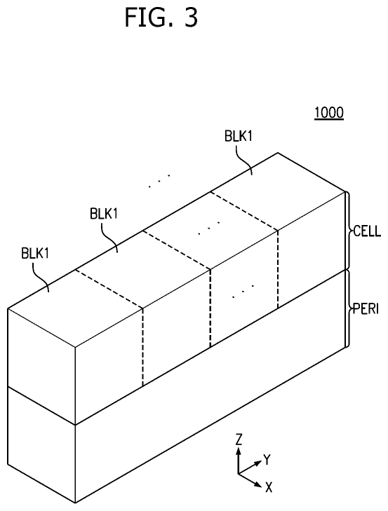

FIG. 3 is a perspective view of a representative configuration of a semiconductor memory device according to some implementations.

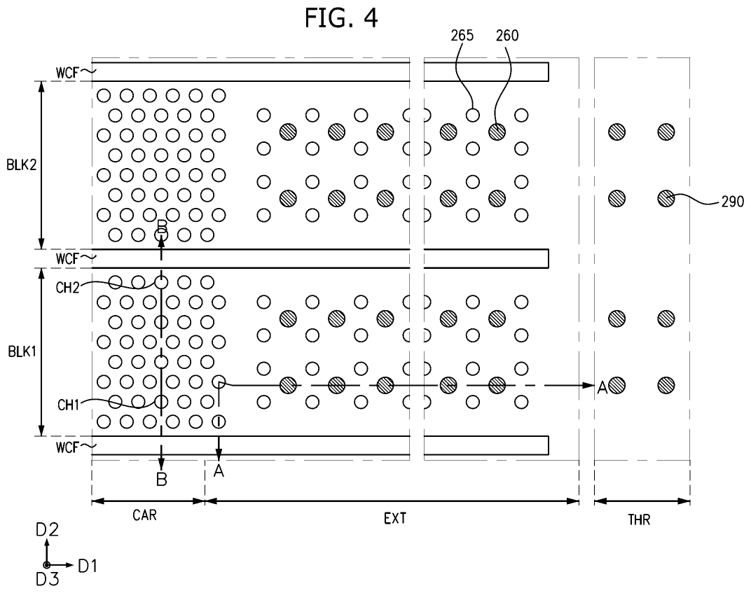

Referring to FIG. 3, a semiconductor device 1000 may include a cell structure CELL and a peripheral circuit structure PERI that overlap each other in a vertical direction Z (e.g., D3 of FIG. 4). The cell structure CELL may include the memory cell array 20 described with reference to FIG. 1, and the peripheral circuit structure PERI may include the peripheral circuit 30 described with reference to FIG. 1.

The cell structure CELL may include the plurality of memory cell blocks BLK1, BLK2, . . . , BLKn. Each of the plurality of memory cell blocks BLK1, BLK2,. BLKn may include memory cells arranged in three dimensions. Detailed structures of the cell structure CELL and the peripheral circuit structure EPRI will be described.

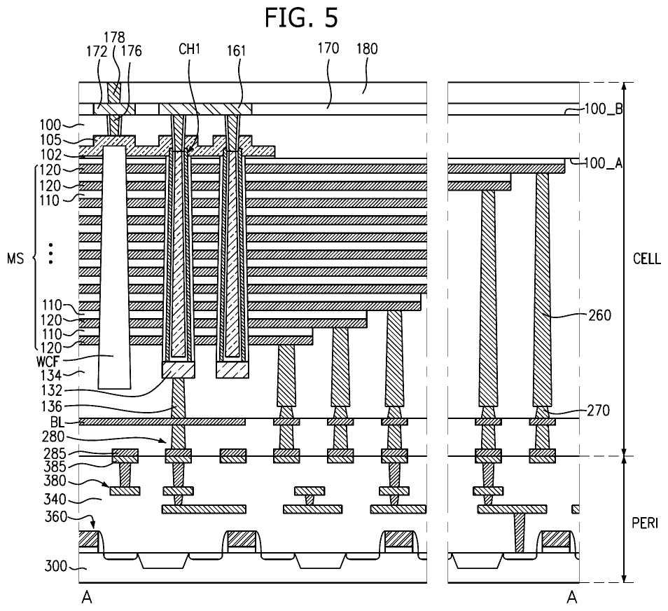

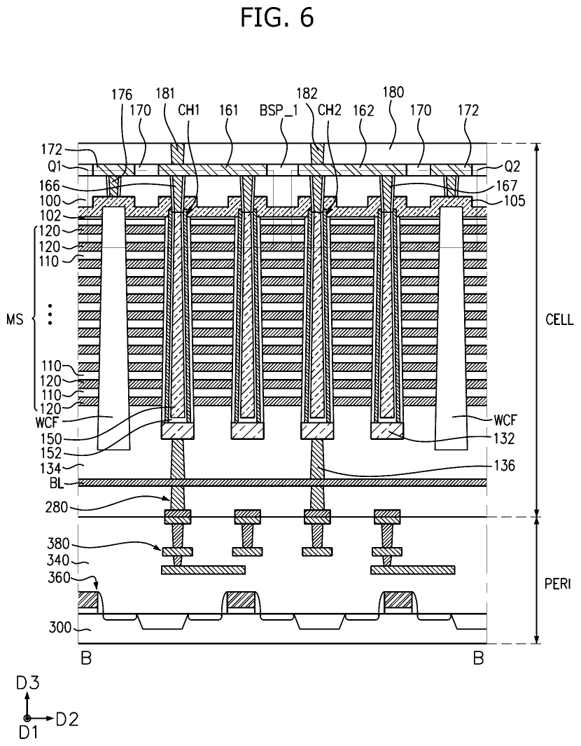

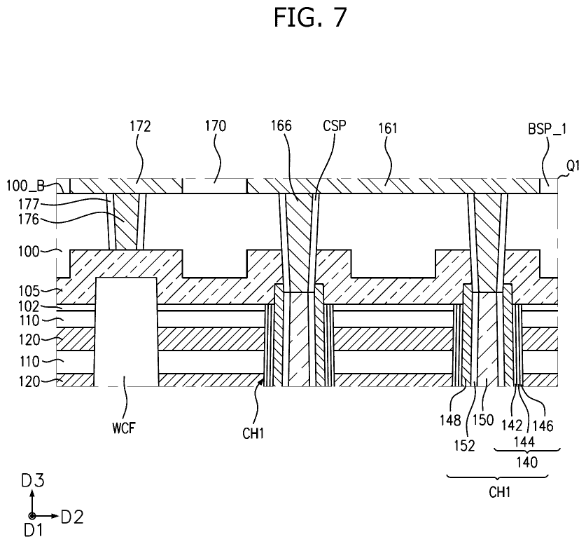

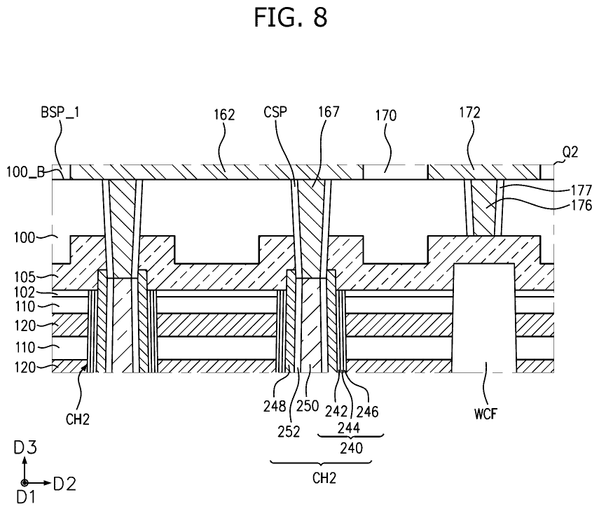

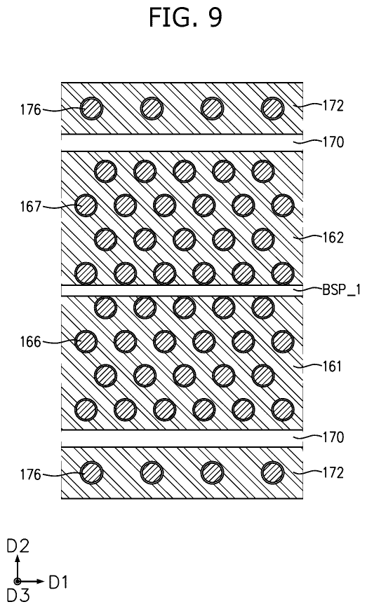

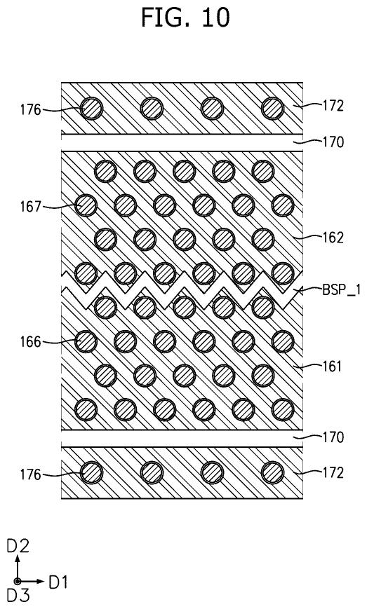

FIG. 4 is an example plan view of a semiconductor memory device according to some implementations. FIG. 5 is a cross-sectional view taken along line A-A of FIG. 4. FIG. 6 is a cross-sectional view taken along line B-B of FIG. 4. FIG. 7 is an enlarged view provided to explain a region Q1 of FIG. 6. FIG. 8 is an enlarged view provided to explain a region Q2 of FIG. 6. FIGS. 9 and 10 are example layout diagrams of the wiring plate and the wiring isolation pattern of FIG. 6.

Referring to FIGS. 4 to 10, the semiconductor memory device according to some implementations may include the cell structure CELL and the peripheral circuit structure PERI.

The cell structure CELL may include an upper insulating layer 100, a common source layer 105, a mold structure MS, a first channel structure CH1, a second channel structure CH2, a first wiring plate 161, a second wiring plate 162, a first vertical gate contact 166, a second vertical gate contact 167, a wiring isolation pattern BSP_1, etc.

The cell structure CELL may include a cell array region CAR, an extension region EXT, and a through region THR.

A memory cell array (e.g., MCA of FIG. 2) including a plurality of memory cells may be formed on the cell array region CAR. The first channel structure CH1, the mold structure MS, the bit line BL, etc. may be disposed on the cell array region CAR. In the present disclosure, the expression “a configuration B is formed (or disposed) on a configuration A” is not limited to the configuration B being formed or disposed in contact with the configuration A. For example, it may also include an aspect in which another configuration C is interposed between the configuration B and the configuration A. In addition, in the disclosure, the expression that “the configuration B is formed or disposed on the configuration A” is not limited to the configuration B being disposed above the configuration A in the drawings. For example, it may also include an aspect in which the configuration B is disposed below, or to the right or left side of the configuration A in the drawing. The extension region EXT may be disposed around the cell array region CAR. For example, the extension region EXT may surround the cell array region CAR. Gate electrodes 120 to be described below may include a staircase structure on the extension region EXT. A word line contact 260, a dummy channel structure 265, etc. may be disposed on the extension region EXT. The through region THR may be disposed outside the extension region EXT. For example, the through region THR may be disposed on one side of the extension region EXT, but implementations are not limited thereto. An input and output contact 290, etc. may be disposed in the through region THR.

The upper insulating layer 100 may be disposed on the mold structure MS and the common source layer 105. The upper insulating layer 100 may cover the mold structure MS and the common source layer 105. For example, the upper insulating layer 100 may include at least one of silicon oxide, silicon oxynitride, and a low-k material having a dielectric constant lower than that of silicon oxide, but implementations are not limited thereto.

The upper insulating layer 100 may include a first side 100_A and a second side 100_B opposite the first side 100_A. The first side 100_A of the upper insulating layer 100 may be defined by a surface on which the mold structure MS is disposed. The first side 100_A of the upper insulating layer 100 may be referred to as a front side of the upper insulating layer 100. The second side 100_B of the upper insulating layer 100 may be referred to as a back side of the upper insulating layer 100.

The common source layer 105 may be disposed between the upper insulating layer 100 and the mold structure MS. The common source layer 105 may be disposed on the cell area CAR. The common source layer 105 may be connected to the first channel structure CH1 and the second channel structure CH2. For example, the common source layer 105 may be electrically connected to a first channel layer 148 of the first channel structure CH1 and a second channel layer 248 of the second channel structure CH2. The common source layer 105 may be provided as the common source line (e.g., CSL of FIG. 2) of the semiconductor memory device. For example, the common source layer 105 may include polycrystalline silicon or metal doped with impurities, but implementations are not limited thereto.

An etch stop film 102 may be disposed on the mold structure MS. The etch stop film 102 may be disposed on a mold insulating layer 110 disposed on the uppermost portion of the mold structure MS. For example, the etch stop film 102 may include polysilicon. In some implementations, the etch stop film 102 may be omitted.

The mold structure MS may be disposed on the common source layer 105 and the first side 100_A of the upper insulating layer 100. The mold structure MS may be disposed on the cell array region CAR and the extension region EXT of the cell structure CELL. The mold structure MS may include a plurality of mold insulating layers 110 and a plurality of gate electrodes 120 alternately stacked in a third direction D3. Each of the mold insulating layers 110 and each of the gate electrodes 120 may have a layered structure extending parallel to the first side 100_A of the upper insulating layer 100. The gate electrodes 120 may be spaced apart from each other by the mold insulating layer 110 and stacked sequentially on the common source layer 105 and the upper insulating layer 100.

In some implementations, some of the plurality of gate electrodes 120 may be provided as the ground select line (e.g., the GSL1, GSL2, and GSL3 in FIG. 2) of the semiconductor memory device. Some other gate electrodes 120 of the plurality of gate electrodes 120 may be provided as the string select line (e.g., the SSL1, SSL2, and SSL3 of FIG. 2) of the semiconductor memory device. For example, a gate electrode 120 of the plurality of gate electrodes 120, which is adjacent to the common source layer 105, may be provided as the ground select line. The gate electrode 120 of the plurality of gate electrodes 120 which is adjacent to the bit line BL may be provided as the string select line. However, implementations are not limited thereto. The arrangement and number of ground select lines and string select lines may vary.

The plurality of gate electrodes 120 and the plurality of mold insulating layers 110 may be formed in a staircase structure on the extension region EXT. The word line contacts 260 may be formed on the plurality of gate electrodes 120 on the extension region EXT. The word line contact 260 may extend in the third direction D3 and may be connected to the gate electrode 120. The word line contact 260 may be electrically connected to the peripheral circuit structure PERI through a connection via 270 and a cell wiring structure 280.

In some implementations, a dummy channel structure 265 may be formed on the mold structure MS of the extension region EXT. The dummy channel structure 265 may be formed in a shape similar to that of the channel structures CH1 and CH2. The dummy channel structure 265 may be disposed around the word line contact 260. The dummy channel structure 265 may support the word line contact 260.

The mold insulating layer 110 may include an insulating material. For example, the mold insulating layer 110 may include at least one of silicon oxide, silicon nitride, and silicon oxynitride, but implementations are not limited thereto.

The gate electrode 120 may include a conductive material. For example, the gate electrode 120 may include a metal such as tungsten (W), cobalt (Co), nickel (Ni), or a semiconductor material such as silicon, but implementations are not limited thereto.

The first channel structure CH1 may be disposed on the cell array region CAR. The first channel structure CH1 may extend (or be elongated) in the third direction D3. The first channel structure CH1 may be formed (or extend) through the mold structure MS. For example, the first channel structure CH1 may be formed (or extend) through and intersect each of the plurality of gate electrodes 120. The first channel structure CH1 may have a pillar shape (e.g., a cylindrical shape) extending (or elongated) in the third direction D3. In some implementations, the cross section of the first channel structure CH1 may have an inclined side such that its width is progressively narrowed toward the upper insulating layer 100. In other words, the width of the first channel structure CH1 in the first direction D1 and/or the second direction D2 may decrease as the distance from the peripheral circuit structure PERI increases. However, implementations are not limited thereto.

The second channel structure CH2 may be disposed on the cell array region CAR. The second channel structure CH2 may extend (or be elongated) in the third direction D3. The second channel structure CH2 may be formed (or extend) through the mold structure MS. For example, the second channel structure CH2 may be formed (or extend) through and intersect each of the plurality of gate electrodes 120. The second channel structure CH2 may have a pillar shape (e.g., a cylindrical shape) extending (or elongated) in the third direction D3. In some implementations, the shape of the second channel structure CH2 may be the same as or similar to the shape of the first channel structure CH1.

In some implementations, the first channel structures CH1 and the second channel structures CH2 may be arranged in a zigzag form. For example, as illustrated in FIG. 4, a first channel structures CH1 may be arranged to alternate with each other in the first direction D1 and the second direction D2, and the second channel structures CH2 may be arranged to alternate with each other in the first direction D1 and the second direction D2. The first channel structures CH1 and the second channel structures CH2 arranged in a zigzag form may further improve the integration density of the semiconductor memory device. In some implementations, the first channel structures CH1 and the second channel structures CH2 may be arranged in a honeycomb form.

The first channel structure CH1 may include a first vertical gate electrode 150, a first insulating liner film 152, the first channel layer 148, and a first information storage film 140.

The first channel layer 148 may extend in the third direction Z through the mold structure MS. Although it is illustrated that the first channel layer 148 has a cup shape, implementations are not limited thereto. For example, the first channel layer 148 may have various shapes such as a cylindrical shape, a rectangular cylindrical shape, a solid pillar shape, etc. For example, the first channel layer 148 may include a semiconductor material such as a single crystal silicon, a polycrystalline silicon, an organic semiconductor material, a carbon nanostructure, etc., although implementations are not limited thereto.

The first information storage film 140 may be interposed between the first channel layer 148 and each gate electrode 120. For example, the first information storage film 140 may extend along an outer surface of the first channel layer 148. For example, the first information storage film 140 may include at least one of silicon oxide, silicon nitride, silicon oxynitride, and a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some implementations, the first information storage film 140 may include multiple layers. The first information storage film 140 may include the first tunnel insulating film 142, a first charge storage film 144, and a first blocking insulating film 146, which are sequentially stacked on the outer surface of the first channel layer 148.

For example, the first tunnel insulating film 142 may include silicon oxide or a high-k material (e.g., aluminum oxide (Al₂O₃), hafnium oxide (HfO₂)) having a higher dielectric constant than the silicon oxide. For example, the first charge storage film 144 may include silicon nitride. For example, the first blocking insulating film 146 may include the silicon oxide or a high-k material (e.g., aluminum oxide (Al₂O₃) or hafnium oxide (HfO₂)) having a higher dielectric constant than the silicon oxide.

In some implementations, the first charge storage film 144 may include a ferroelectric material. In this case, the first charge storage film 144 may include a metal oxide having ferroelectric properties. For example, the first charge storage film 144 may include a ferroelectric material capable of storing data by hysteresis behavior by voltage applied to the first charge storage film 144. For example, the first charge storage film 144 may include at least one of hafnium oxide, zirconium oxide, and hafnium zirconium oxide.

The first vertical gate electrode 150 may extend in the third direction D3. The first vertical gate electrode 150 may have a vertical pillar shape, and the first insulating liner film 152 may be disposed on a sidewall of the first vertical gate electrode 150. The first vertical gate electrode 150 may be electrically insulated from the first channel layer 148 by the first insulating liner film 152 interposed therebetween. The first insulating liner film 152 may cover a lower surface of the first vertical gate electrode 150. The first vertical gate electrode 150 may be insulated from a channel pad 132 by the first insulating liner film 152.

In some implementations, the first vertical gate electrode 150 may include a doped polysilicon layer, but implementations are not limited thereto. When a data write operation, read operation, or erase operation of the memory cells (e.g., MCT1 to MCT8 of FIG. 2) are performed, a predetermined voltage (or signal) may be applied to the first vertical gate electrode 150 from the back gate lines (BGL1 to BGL3 of FIG. 2).

The second channel structure CH2 may include a second vertical gate electrode 250, a second liner insulating film 252, the second channel layer 248, and a second information storage film 240. In some implementations, the second information storage film 240 may include multiple layers. The second information storage film 240 may include a second tunnel insulating film 242, a second charge storage film 244, and a second blocking insulating film 246, which are sequentially stacked on the outer surface of the second channel layer 248. The description of the components of the second channel structure CH2 may be substantially the same as the description of the components of the first channel structure CH1. The second channel structure CH2 will be described mainly based on differences from the first channel structure CH1.

The first channel structure CH1 may include a first end and a second end facing the first end in the third direction D3. The first end of the first channel structure CH1 may be connected to the common source layer 105. The second end of the first channel structure CH1 may be an end adjacent to the peripheral circuit structure PERI.

In some implementations, the channel pad 132 may be disposed on the second end of the first channel structure CH1. The channel pad 132 may be formed to be connected to the first channel layer 148. For example, the channel pad 132 may be provided in the interlayer insulating film 134 and connected to one end of the first channel layer 148. For example, the channel pad 132 may include polysilicon doped with impurities, but implementations are not limited thereto.

The first wiring plate 161, the second wiring plate 162, and the wiring isolation pattern BSP_1 will be described in detail with reference to FIGS. 6 to 10.

In some implementations, an uppermost portion of the first channel layer 148 may be disposed at a higher level than an upper surface of the first vertical gate electrode 150 and an upper surface of the first information storage film 140. The uppermost portion of the first channel layer 148 may protrude from the upper surface of the first vertical gate electrode 150. The uppermost portion of the first channel layer 148 may protrude from the upper surface of the first information storage film 140. The protruding first channel layer 148 may be in contact with the common source layer 105. At the first end of the first channel structure CH1, the first vertical gate contact 166 may be disposed on the upper surface of the first vertical gate electrode 150. The first vertical gate contact 166 may be formed (or extend) through the upper insulating layer 100 and the common source layer 105. The first vertical gate contact 166 may be electrically connected to the first vertical gate electrode 150.

The contact spacer CSP may surround a side surface of the first vertical gate contact 166. The contact spacer CSP may be disposed between the first vertical gate contact 166 and the common source layer 105. The contact spacer CSP may insulate between the first vertical gate contact 166 and the common source layer 105. A portion of the contact spacer CSP may be disposed between the first channel layer 148 and the first vertical gate contact 166.

The first wiring plate 161 may be disposed on the second side 100_B of the upper insulating layer 100 and on an upper surface of the first vertical gate contact 166. The first wiring plate 161 may be electrically connected to the first vertical gate contact 166. That is, the first wiring plate 161 may be electrically connected to the first vertical gate electrode 150 of the first channel structure CH1 through the first vertical gate contact 166.

At the first end of the second channel structure CH2, the second vertical gate contact 167 may be disposed on an upper surface of the second vertical gate electrode 250. The second vertical gate contact 167 may be formed through the upper insulating layer 100 and the common source layer 105. The second vertical gate contact 167 may be electrically connected to the second vertical gate electrode 250.

The contact spacer CSP may surround a side surface of the second vertical gate contact 167. The contact spacer CSP may be disposed between the second vertical gate contact 167 and the common source layer 105. The contact spacer CSP may insulate between the second vertical gate contact 167 and the common source layer 105. A portion of the contact spacer CSP may be disposed between the second channel layer 248 and the second vertical gate contact 167.

The second wiring plate 162 may be disposed on the second side 100_B of the upper insulating layer 100 and an upper surface of the second vertical gate contact 167. The second wiring plate 162 may be electrically connected to the second vertical gate contact 167. That is, the second wiring plate 162 may be electrically connected to the second vertical gate electrode 250 of the second channel structure CH2 through the second vertical gate contact 167.

The first wiring plate 161 may extend in the first direction D1. The first wiring plate 161 may overlap a plurality of first channel structures CH1 and a plurality of first vertical gate contacts 166 in the third direction D3. A plurality of first vertical gate electrodes 150 may be connected to one first wiring plate 161.

The second wiring plate 162 may extend in the first direction D1. The second wiring plate 162 may overlap a plurality of second channel structures CH2 and a plurality of second vertical gate contacts 167 in the third direction D3. A plurality of second vertical gate electrodes 250 may be connected to one second wiring plate 162.

The wiring isolation pattern BSP_1 may be disposed between the first wiring plate 161 and the second wiring plate 162. The wiring isolation pattern BSP_1 may extend (or be elongated) in the first direction D1. The first wiring plate 161 may be spaced apart from the second wiring plate 162 in the second direction D2 by the wiring isolation pattern BSP_1. The wiring isolation pattern BSP_1 may insulate the first wiring plate 161 and the second wiring plate 162.

As illustrated in FIG. 9, the wiring isolation pattern BSP_1 may extend (or be elongated) linearly along a side surface of the first wiring plate 161 and a side surface of the second wiring plate 162.

In another aspect, as illustrated in FIG. 10, the wiring isolation pattern BSP_1 may be elongated in a zigzag pattern in the first direction D1 between the first vertical gate contact 166 and the second vertical gate contact 167.

FIGS. 9 and 10 illustrate that the wiring isolation pattern BSP_1 does not overlap the first vertical gate contact 166 and the second vertical gate contact 167 in the third direction D3, but implementations are not limited thereto. For example, the wiring isolation pattern BSP_1 may partially overlap the first vertical gate contact 166 and/or the second vertical gate contact 167 in the third direction D3.

A common source contact 176 may be formed through the upper insulating layer 100 and may be disposed on the common source layer 105. The common source contact 176 may be connected to the common source layer 105. An upper surface of the common source contact 176, the upper surface of the first vertical gate contact 166, and the upper surface of the second vertical gate contact 167 may be disposed at the same level. In other words, the upper surface of the common source contact 176, the upper surface of the first vertical gate contact 166, and the upper surface of the second vertical gate contact 167 may be disposed on the same plane.

A source contact spacer 177 may be disposed on a side surface of the common source contact 176. The source contact spacer 177 may surround the side surface of the common source contact 176. In some implementations, the source contact spacer 177 and the contact spacer CSP may be formed by the same process. However, implementations are not limited thereto. For example, the source contact spacer 177 and the contact spacer CSP may be formed by different processes. In addition, as another example, the source contact spacer 177 may be omitted, and the common source contact 176 may be in contact with the upper insulating layer 100.

A common source wiring layer 172 may be disposed on the upper surface of the common source contact 176 and on the second side 100_B of the upper insulating layer 100. The common source wiring layer 172 may be electrically connected to the common source contact 176. The common source wiring layer 172 may extend in the first direction D1. At least one common source contact 176 may be connected to one common source wiring layer 172.

A mold isolation structure WCF may separate the mold structure MS. The mold isolation structure WCF may extend (or be elongated) in the first and third directions D1 and D3. The mold isolation structure WCF may include an insulating material, for example, at least one of silicon oxide, silicon nitride, and silicon oxynitride, but implementations are not limited thereto.

A plurality of mold isolation structures WCF may be provided. The first channel structure CH1 and the second channel structure CH2 may be disposed between two adjacent mold isolation structures WCF of a plurality of mold isolation structures WCF. In addition, a plurality of mold isolation structures WCF may be provided. The first wiring plate 161, the second wiring plate 162, and the wiring isolation pattern BSP_1 may be disposed between two adjacent mold isolation structures WCF of the plurality of mold isolation structures WCF.

In some implementations, a plurality of common source contacts 176 may be provided. Each of the plurality of common source contacts 176 may overlap each of the plurality of mold isolation structures WCF in the third direction D3. The common source contact 176 may be spaced apart from the first wiring plate 161 in the first direction D1. The common source contact 176 may be spaced apart from the second wiring plate 162 in the first direction D1. A first wiring insulating layer 170 may be disposed between the common source contact 176 and the first wiring plate 161 and between the common source contact 176 and the second wiring plate 162, respectively.

In some implementations, as illustrated in FIG. 4, two adjacent mold isolation structures WCF of the plurality of mold isolation structures WCF may define memory cell blocks BLK1 and BLK2.

For example, the two mold isolation structures WCF of FIG. 6 may define a first memory cell block BLK1. In this case, the first channel structure CH1 and the second channel structure CH2 may be disposed in the first memory cell block BLK1. In addition, the first wiring plate 161, the second wiring plate 162, and the wiring isolation pattern BSP_1 may be disposed in the first memory cell block BLK1.

Although FIG. 6 illustrates that there are four channel structures CH1 and CH2 in the first memory cell block BLK1 along the second direction D2, implementations are not limited thereto. For example, the number of channel structures CH1 and CH2 disposed along the second direction D2 may be five or more.

In some implementations, a sub-mold isolation structure may be disposed in the memory cell blocks BLK1 and BLK2. The sub-mold isolation structure may separate a portion of the mold structure MS from the memory cell blocks BLK1 and BLK2. One or more sub-mold isolation structures may be disposed in the memory cell blocks BLK1 and BLK2.

A first wiring contact 181 may be disposed on the first wiring plate 161. A second wiring contact 182 may be disposed on the second wiring plate 162. Each of the first wiring contact 181 and the second wiring contact 182 may be electrically connected to the peripheral circuit structure PERI.

Each of the first wiring contact 181 and the second wiring contact 182 may be electrically connected to a peripheral circuit element 360 of the peripheral circuit structure PERI through a through via extending in the third direction D3.

The peripheral circuit structure PERI may provide a signal to the first wiring plate 161 and the second wiring plate 162. The peripheral circuit structure PERI may provide a first signal to the first vertical gate electrode 150 through the first wiring contact 181, the first wiring plate 161, and the first vertical gate contact 166. The peripheral circuit structure PERI may provide a second signal to the second vertical gate electrode 250 through the second wiring contact 182, the second wiring plate 162, and the second vertical gate contact 167. The peripheral circuit structure PERI may independently control the first signal provided to the first vertical gate electrode 150 and the second signal provided to the second vertical gate electrode 250. In one example, the first signal and the second signal may be different signals, or they may be the same signal in another example.

If capacitance and/or resistance increases in the semiconductor memory device, an RC delay may deteriorate, which may worsen the electrical characteristics of the semiconductor memory device. If the vertical gate electrodes 150 and 250 are used in the channel structures CH1 and CH2, a capacitance value may increase and thus the RC delay of the semiconductor memory device may increase.

On the other hand, in the semiconductor memory device according to some implementations, two or more wiring plates may be disposed in one memory cell block. For example, the first wiring plate 161 connected to the first vertical gate electrode 150 and the second wiring plate 162 connected to the second vertical gate electrode 250 may be formed, and each of the first wiring plate 161 and the second wiring plate 162 may be operated independently, which may reduce the capacitance value of the semiconductor memory device and improve the RC delay. Accordingly, electrical characteristics of the semiconductor memory device can be improved.

A bit line contact 136 may be disposed on the channel pad 132. The bit line contact 136 may be connected to the channel pad 132. The bit line contact 136 may be disposed in the interlayer insulating film 134. A bit line BL may be disposed on the bit line contact 136 and the interlayer insulating film 134. The bit line BL may be connected to the bit line contact 136. The bit line BL may extend in the second direction D2. The bit line BL may intersect the mold isolation structure WCF. The bit line BL may be connected to the first channel structure CH1 and the second channel structure CH2 arranged along the second direction D2. The cell wiring structure 280 may be disposed on the bit line BL.

The peripheral circuit structure PERI may include a peripheral circuit substrate 300, a peripheral circuit element 360, and a peripheral circuit wiring structure 380.

For example, the peripheral circuit substrate 300 may include a semiconductor substrate such as a silicon substrate, a germanium substrate, or a silicon-germanium substrate. Alternatively, the peripheral circuit substrate 300 may also include a silicon-on-insulator (SOI) substrate or a germanium-on-insulator (GOI) substrate, etc.

The peripheral circuit element 360 may be formed on the peripheral circuit substrate 300. The peripheral circuit element 360 may form a peripheral circuit that controls an operation of the semiconductor memory device. For example, the peripheral circuit element 360 may include the row decoder 32, the page buffer 34, the data input and output circuit 36, the control logic 38, etc. of FIG. 1. In the following description, the surface of the peripheral circuit substrate 300 on which the peripheral circuit element 360 is disposed may be referred to as a front side of the peripheral circuit substrate 300. Conversely, the surface of the peripheral circuit substrate 300 opposite to the front side of the peripheral circuit substrate 300 may be referred to as a back side of the peripheral circuit substrate 300.

For example, the peripheral circuit element 360 may include a transistor, but implementations are not limited thereto. For example, the peripheral circuit element 360 may include not only various active elements such as transistors, etc., but also various passive elements such as capacitors, resistors, inductors, etc.

The peripheral circuit wiring structure 380 may be formed on the peripheral circuit element 360.

For example, a second wiring insulating film 340 may be formed on the front side of the peripheral circuit substrate 300, and the peripheral circuit wiring structure 380 may be formed in the second wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and implementations are not limited thereto.

In some implementations, the cell structure CELL may be stacked on the peripheral circuit structure PERI. For example, the cell structure CELL may be stacked on the second wiring insulating film 340.

In some implementations, the first side 100_A of the upper insulating layer 100 may be opposite to the peripheral circuit structure PERI. For example, the front side (i.e., the first side 100_A) of the upper insulating layer 100 may be opposite to the front side of the peripheral circuit substrate 300. The semiconductor memory device according to some implementations may have a chip-to-chip (C2C) structure. The C2C structure refers to manufacturing an upper chip including the cell structure (CELL) on a first wafer, manufacturing a lower chip including the peripheral circuit structure (PERI) on the second wafer (e.g., the peripheral circuit substrate 300) that is different from the first wafer, and connecting the upper and lower chips to each other by a bonding method.

In some implementations, by the bonding method, it may mean a method of electrically connecting a first bonding metal 285 formed on the lowermost metal layer of the upper chip and a second bonding metal 385 formed on the uppermost metal layer of the lower chip to each other. For example, if the first bonding metal 285 and the second bonding metal 385 are formed of copper (Cu), the bonding method may be a Cu-Cu bonding method. However, this is only an example, and the first bonding metal 285 and the second bonding metal 385 may be formed of various other metals such as aluminum (Al), tungsten (W), etc.

As the first bonding metal 285 and the second bonding metal 385 are bonded to each other, the cell wiring structure 280 may be connected to the peripheral circuit wiring structure 380. Accordingly, the bit line BL and/or each of the gate electrodes 120 may be electrically connected to the peripheral circuit element 360.

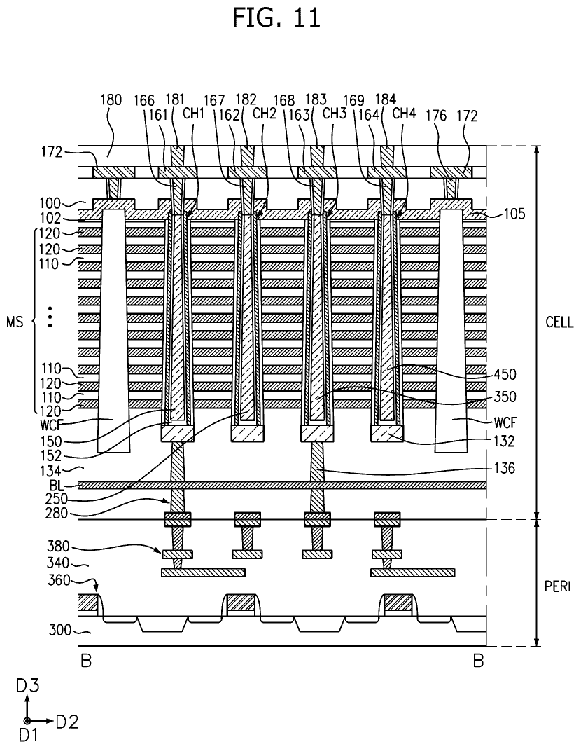

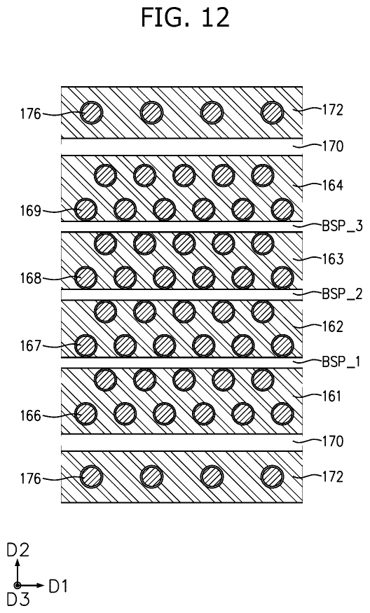

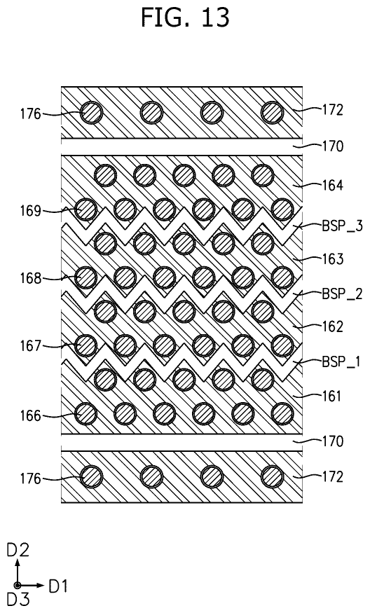

FIG. 11 is a diagram provided to explain a semiconductor memory device according to some implementations. FIGS. 12 and 13 are example layout diagrams of the wiring plate and the wiring isolation pattern of FIG. 11. For convenience of description, different configurations from those described in FIGS. 4 to 10 will be mainly described.

Referring to FIGS. 11 to 13, in the semiconductor memory device according to some implementations, the cell structure CELL may include wiring isolation patterns BSP_1, BSP_2, and BSP_3.

A plurality of channel structures CH1, CH2, CH3, and CH4 may be disposed on the mold structure MS. Description of the plurality of channel structures CH1, CH2, CH3, and CH4 may be substantially the same as the description of the first channel structure CH1 described above. Accordingly, differences will be mainly described below.

The first vertical gate contact 166 and the first wiring plate 161 may be disposed on the first vertical gate electrode 150 of the first channel structure CH1. The second vertical gate contact 167 and the second wiring plate 162 may be disposed on the second vertical gate electrode 250 of the second channel structure CH2. A third vertical gate contact 168 and a third wiring plate 163 may be disposed on a third vertical gate electrode 350 of the third channel structure CH3. A fourth vertical gate contact 169 and a fourth wiring plate 164 may be disposed on a fourth vertical gate electrode 450 of the fourth channel structure CH4.

The first to fourth wiring plates 161, 162, 163 and 164 may extend in the first direction D1. The first to fourth wiring plates 161, 162, 163 and 164 may be disposed between two adjacent mold isolation structures WCF. In addition, the first to fourth wiring plates 161, 162, 163, and 164 may be disposed between two adjacent common source wiring layers 172. Although it is illustrated that the number of wiring plates 161, 162, 163, and 164 is four, implementations are not limited thereto.

For example, the number of wiring plates 161, 162, 163, and 164 may be three or five or more.

A first wiring isolation pattern BSP_1 may be disposed between the first wiring plate 161 and the second wiring plate 162. A second wiring isolation pattern BSP_2 may be disposed between the second wiring plate 162 and the third wiring plate 163. A third wiring isolation pattern BSP_3 may be disposed between the third wiring plate 163 and the fourth wiring plate 164. The first to third wiring isolation patterns BSP_1, BSP_2, and BSP_3 may extend in the first direction D1. The wiring isolation patterns BSP_1, BSP_2, and BSP_3 may insulate between adjacent wiring plates 161, 162, 163 and 164. As illustrated in FIG. 12, the wiring isolation patterns BSP_1, BSP_2, and BSP_3 may have a linear shape extending in the first direction D1. In another aspect, as illustrated in FIG. 13, the wiring isolation patterns BSP_1, BSP_2, and BSP_3 may have a zigzag shape extending in the first direction D1.

The first wiring contact 181 may be disposed on the first wiring plate 161. The second wiring contact 182 may be disposed on the second wiring plate 162. A third wiring contact 183 may be disposed on the third wiring plate 163. A fourth wiring contact 184 may be disposed on the fourth wiring plate 164. Each of the first to fourth wiring contacts 181, 182, 183, and 184 may be electrically connected to the peripheral circuit structure PERI.

The peripheral circuit structure PERI may provide a signal to each of the first to fourth wiring plates 161, 162, 163 and 164. The peripheral circuit structure PERI may independently control signals provided to the first to fourth wiring plates 161, 162, 163 and 164. That is, the peripheral circuit structure PERI may independently control signals provided to the first to fourth vertical gate electrodes 150, 250, 350 and 450.

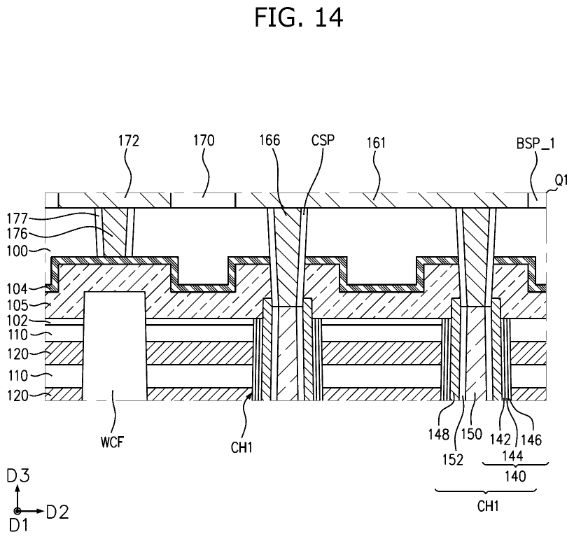

FIG. 14 is a diagram provided to explain a semiconductor memory device according to some implementations. For reference, FIG. 14 may correspond to an enlarged view of the region Q1 of FIG. 6. For convenience of description, different configurations from those described in FIGS. 4 to 10 will be mainly described.

Referring to FIG. 14, in the semiconductor memory devices according to some implementations, the cell structure CELL may further include an upper conductive layer 104 disposed on the common source layer 105.

The upper conductive layer 104 may be disposed on an upper surface of the common source layer 105. The upper conductive layer 104 may cover the upper surface of the common source layer 105. The upper conductive layer 104 may be disposed between the common source layer 105 and the upper insulating layer 100. The upper conductive layer 104 may include a conductive material. The upper conductive layer 104 may include, for example, a metal nitride such as titanium nitride, tantalum nitride, tungsten nitride, a metal such as tungsten, molybdenum, chromium, nickel, cobalt, tantalum, a metal silicide such as tungsten silicide, nickel silicide, cobalt silicide, tantalum silicide, or a combination thereof. In some implementations, the upper conductive layer 104 may include a plurality of layers in which two or more different material layers are stacked.

The common source contact 176 may be disposed on the upper conductive layer 104. The common source contact 176 may be connected to the common source layer 105 through the upper conductive layer 104. The first vertical gate contact 166 may be formed through the upper conductive layer 104 and the common source layer 105 to be connected to the first vertical gate electrode 150. The contact spacer CSP may be disposed between the upper conductive layer 104 and the first vertical gate contact 166.

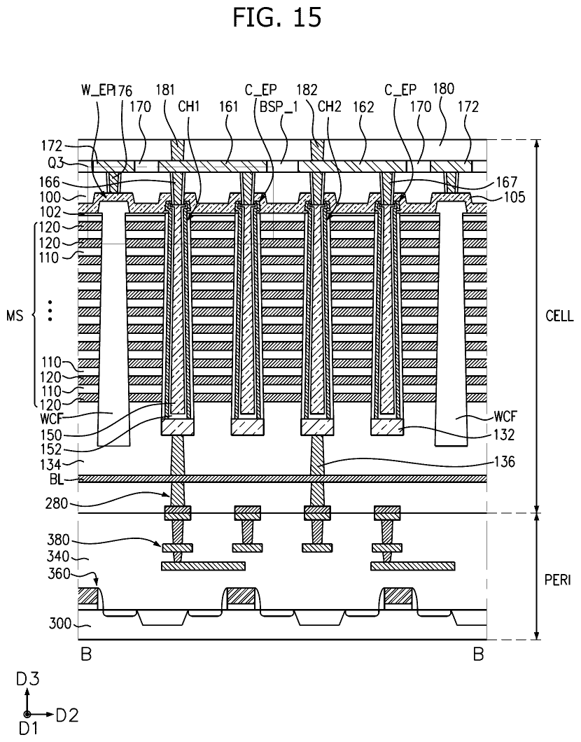

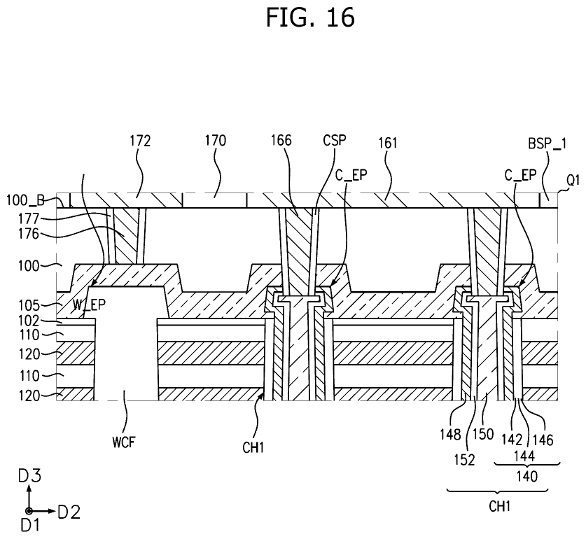

FIGS. 15 and 16 are diagrams provided to explain a semiconductor memory device according to some implementations. FIG. 16 is an enlarged view provided to explain a region Q3 of FIG. 15. For convenience of description, different configurations from those described in FIGS. 4 to 10 will be mainly described.

Referring to FIGS. 15 and 16, an end of each of the first channel structure CH1 and the second channel structure CH2 may include an expanded portion C_EP expanding in a horizontal direction. Since the description of the expanded portion C_EP of the second channel structure CH2 is substantially the same as the expanded portion C_EP of the first channel structure CH1, the expanded portion C_EP of the first channel structure CH1 will be mainly described.

The first channel structure CH1 may include the expanded portion C_EP disposed at a first end. The expanded portion C_EP of the first channel structure CH1 may be disposed on the common source layer 105. The expanded portion C_EP of the first channel structure CH1 may have an expanding width in the first direction D1 and the second direction D2. Specifically, the width of the first channel layer 148 disposed on the expanded portion C_EP of the first channel structure CH1 may be greater than the width of at least a portion of the first channel layer 148 disposed in the mold structure MS. The width of the first channel layer 148 may refer to the width in the first or second directions D1 and D2 or both directions. For example, the width of the first channel layer 148 disposed on the expanded portion C_EP of the first channel structure CH1 may be greater than the width of the first channel layer 148 surrounded by the gate electrode 120 disposed on the uppermost portion.

A step may be formed between the first channel layer 148 disposed on the expanded portion C_EP of the first channel layer 148 and the first channel layer 148 disposed on the remaining portion. The expanded portion C_EP may be defined by a portion disposed above the step. The insulating liner film 152 may be disposed on the expanded portion C_EP along a profile of the first channel layer 148.

The first vertical gate electrode 150 on the expanded portion C_EP may have a shape expanding in the first direction D1 and the second direction D2. For example, an uppermost portion of the first vertical gate electrode 150 may have a shape extending in the first direction D1 and the second direction D2. The first vertical gate electrode 150 may be formed such that the uppermost portion thereof has a relatively expanded width, and this ensures a relatively large contact area between the first vertical gate electrode 150 and the first vertical gate contact 166.

In some implementations, the mold isolation structure WCF may include an expanded portion W_EP disposed at one end thereof. The expanded portion W_EP of the mold isolation structure WCF may be disposed on the common source layer 105. The expanded portion W_EP of the mold isolation structure WCF may have an expanding width in the first direction D1 and the second direction D2. A step may be formed between a portion disposed on the expanded portion W_EP of the mold isolation structure WCF and the remaining portion.

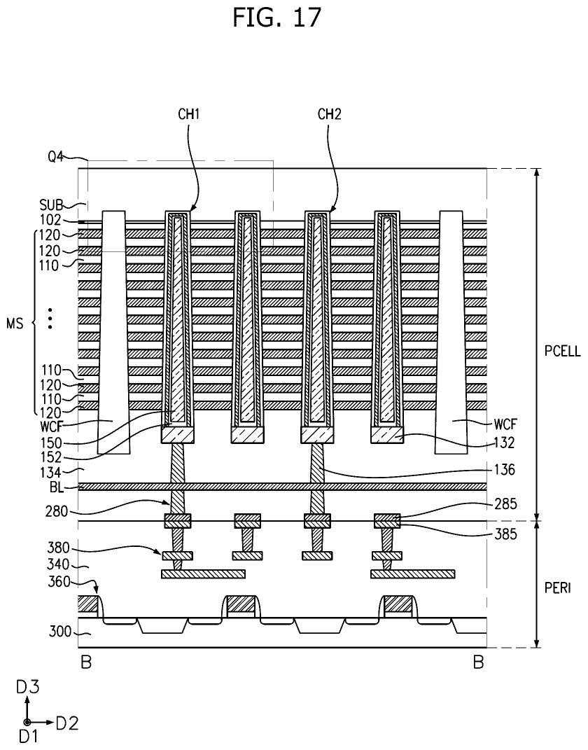

FIGS. 17 to 23 are diagrams illustrating intermediate stages, which are provided to explain a method for manufacturing a semiconductor memory device according to some implementations.

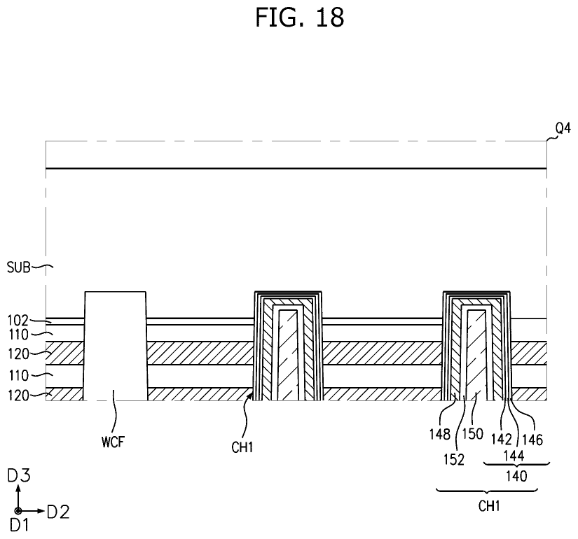

FIG. 17 may correspond to a cross-sectional view taken along line B-B of FIG. 4. FIGS. 18 to 23 are enlarged views provided to explain the region Q4 of FIG. 17.

Referring to FIGS. 17 and 18, a pre-cell structure PCELL may be bonded onto the peripheral circuit structure PERI.

Specifically, the pre-cell structure PCELL may be formed on the first wafer, and the peripheral circuit structure PERI may be formed on the second wafer.

The pre-cell structure PCELL may include a cell substrate SUB, the mold structure MS, the first channel structure CH1, the second channel structure CH2, the mold isolation structure WCF, the bit line BL, the cell wiring structure 280, etc.

For example, the cell substrate SUB may include a semiconductor substrate such as a silicon substrate, a germanium substrate, or a silicon-germanium substrate. Alternatively, the cell substrate SUB may include a silicon-on-insulator (SOI) substrate, a germanium-on-insulator (GOI) substrate, etc. In some implementations, the cell substrate SUB may include polysilicon (poly Si).

The mold structure MS, the first channel structure CH1, the second channel structure CH2, the mold isolation structure WCF, the bit line BL, etc. may be formed on the cell substrate SUB. The first end of the first channel structure CH1 and the first end of the second channel structure CH2 may be disposed in the cell substrate SUB.

The pre-cell structure PCELL may be bonded onto the peripheral circuit structure PERI. For example, the first bonding metal 285 of the pre-cell structure PCELL and the second bonding metal 385 of the peripheral circuit structure PERI may be bonded.

In the following description of a manufacturing method, the description of the second channel structure CH2 is substantially the same as the description of the first channel structure CH1, and thus differences will be mainly described below.

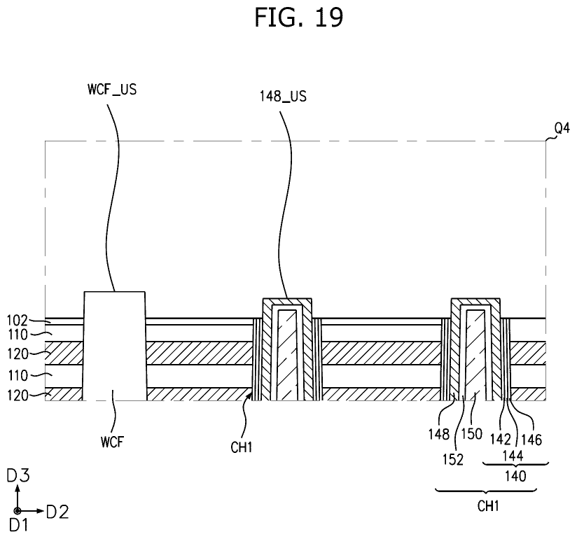

Referring to FIGS. 18 and 19, the cell substrate SUB may be removed, and a portion of the first channel structure CH1 and a portion of the second channel structure may be removed.

The cell substrate SUB may be removed by a grinding process and an etching process. The cell substrate SUB may be removed to expose an upper surface WCF_US of the mold isolation structure WCF, an upper portion of the first channel structure CH1, and the etch stop film 102. A portion of the information storage film 140 may be removed to expose an upper surface 148_US of the first channel layer 148.

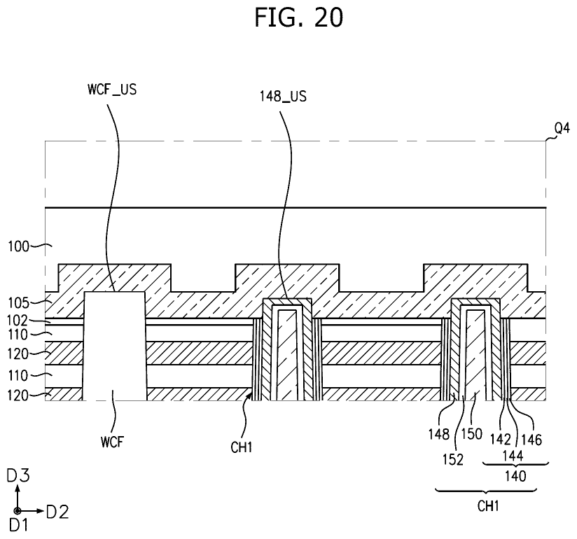

Referring to FIG. 20, the common source layer 105 may be formed on the etch stop film 102, the mold isolation structure WCF, the first channel structure CH1, and the second channel structure, and the upper insulating layer 100 may be formed on the common source layer 105.

In detail, the common source layer 105 may cover the upper surface WCF_US of the mold isolation structure WCF and the upper surface 148_US of the first channel layer 148. The common source layer 105 may be formed by using polysilicon. For example, the common source layer 105 may be formed by using polysilicon doped with impurities. The upper insulating layer 100 may be formed on the common source layer 105.

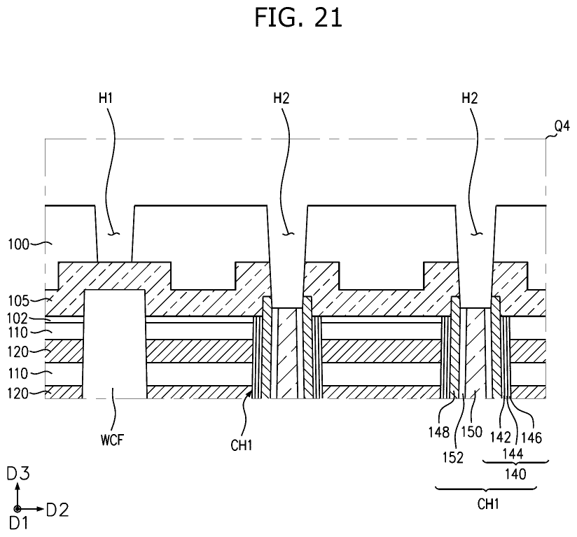

Referring to FIG. 21, using an etching process, a first hole H1 and a second hole H2 may be formed in the upper insulating layer 100.

Specifically, a mask pattern may be formed on the upper insulating layer 100. The first hole H1 and the second hole H2 may be formed by using the mask pattern as an etching mask. The first hole H1 may overlap the mold isolation structure WCF in the third direction D3. The first hole H1 may expose a portion of the common source layer 105. The second hole H2 may overlap the first channel structure CH1 in the third direction D3. The second hole H2 may expose an upper surface of the first vertical gate electrode 150 and a portion of the first channel layer 148.

In some implementations, the first hole H1 and the second hole H2 may be formed by separate processes. For example, the first hole H1 may be formed by using the first etching process, and the second hole H2 may be formed by using the second etching process.

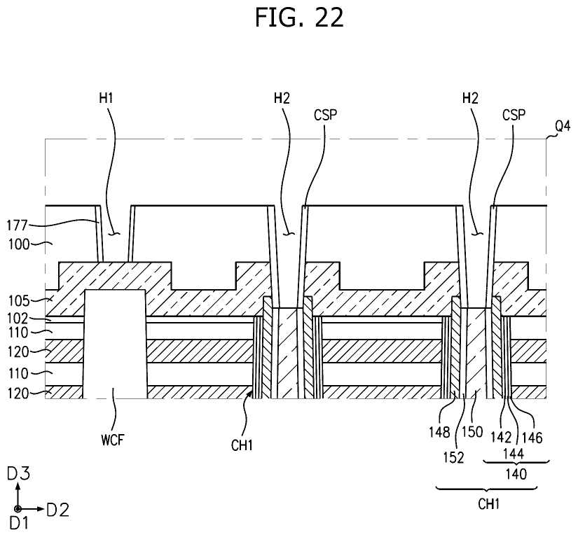

Referring to FIG. 22, the source contact spacer 177 and the contact spacer CSP may be formed.

Specifically, the source contact spacer 177 may be formed on a sidewall of the first hole H1. In addition, the contact spacer CSP may be formed on a sidewall of the second hole H2. The contact spacer CSP may cover the first channel layer 148 and the common source layer 105 exposed by the second hole H2. In some implementations, the source contact spacer 177 and the contact spacer CSP may be formed by the same process.

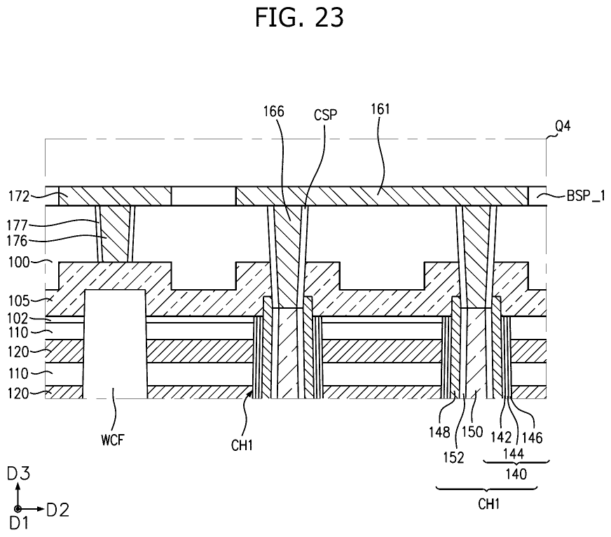

Referring to FIGS. 22 and 23, the common source contact 176 may be formed on the common source layer 105 and the first vertical gate contact 166 may be formed on the first vertical gate electrode 150.

The common source contact 176 may fill the interior of the first hole H1, and the first vertical gate contact 166 may fill the interior of the second hole H2. The common source contact 176 and the first vertical gate contact 166 may be formed by the same process.

For example, a conductive layer may be formed in the first hole H1 and the second hole H2 using a metal such as tungsten, nickel, cobalt, tantalum, a metal nitride such as titanium nitride, tantalum nitride, tungsten nitride, a metal silicide such as titanium nickel silicide, cobalt silicide, tantalum silicide, or a combination thereof, and an upper portion of the conductive layer may be planarized to form the common source contact 176 and the first vertical gate contact 166. Accordingly, the upper surface of the common source contact 176 and the upper surface of the first vertical gate contact 166 may be disposed at the same level.

The source wiring layer 172 may be formed on the common source contact 176 and the first wiring plate 161 may be formed on the first vertical gate contact 166. The second wiring plate (e.g., 162 of FIG. 6) may also be formed upon formation of the first wiring plate 161.

Referring to FIGS. 6 and 23, a conductive layer may be formed on the upper insulating layer 100. A mask pattern may be formed on the conductive layer, and the conductive layer may be patterned using the mask pattern as an etching mask. The source wiring layer 172, the first wiring plate 161, and the second wiring plate 162 may be formed by patterning the conductive layer. The wiring isolation pattern BSP_1 and the first wiring insulating layer 170 may be formed on the upper insulating layer 100.

In another aspect, an insulating layer may be formed on the upper insulating layer 100, and the insulating layer may be patterned to form the wiring isolation pattern BSP_1 and the first wiring insulating layer 170. The source wiring layer 172, the first wiring plate 161, and the second wiring plate 162 may be formed on the upper insulating layer 100.

Referring to FIGS. 5 and 6, a second upper insulating layer 180, the first wiring contact 181, and the second wiring contact 182 may be formed on the source wiring layer 172, the first wiring plate 161, and the second wiring plate 162. The first wiring contact 181 may be connected to the first wiring plate 161, and the second wiring contact 182 may be connected to the second wiring plate 162.

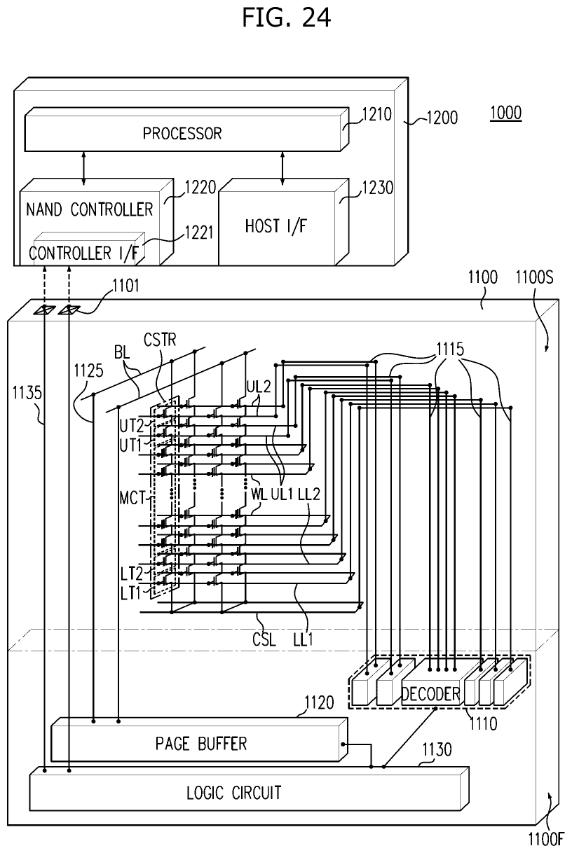

FIG. 24 is an example block diagram provided to explain an electronic system according to some implementations.

Referring to FIG. 24, an electronic system 1000 may include a semiconductor memory device 1100 described above with reference to FIGS. 1 to 16, and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 16. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various implementations.

In some implementations, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor from among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some implementations, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware and may control the NAND controller 1220 to access the semiconductor memory device 1100. The NAND controller 1220 may include a NAND controller interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND controller interface 1221. The host interface 1230 may provide a communication function between the electronic system 1000 and an external host. Upon receiving a control command from the external host through the host interface 1230, the processor 1210 may control the semiconductor memory device 1100 in response to the control command.

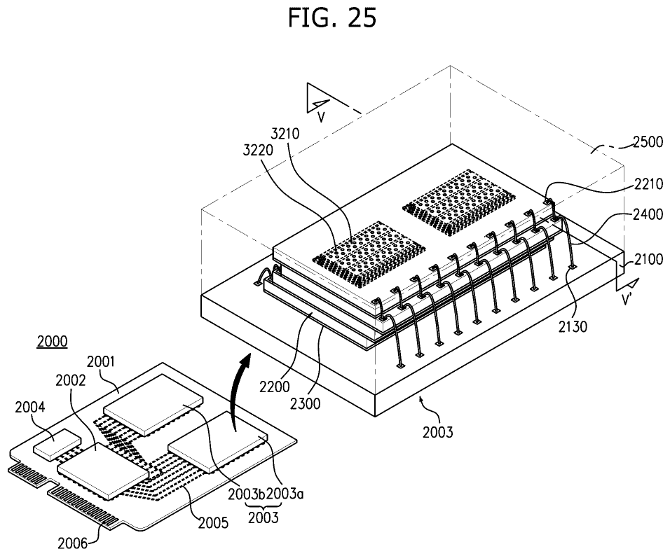

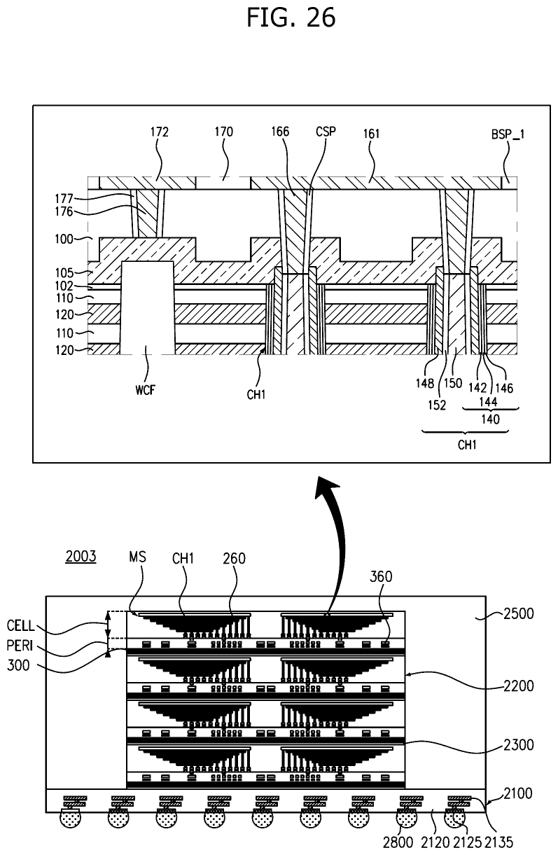

FIG. 25 is an example perspective view illustrating an electronic system including a semiconductor memory device according to some implementations. FIG. 26 is a schematic cross-sectional view taken along line V-V′ of FIG. 24.

Referring to FIG. 25, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host.

In some implementations, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some implementations, the electronic system 2000 may operate by the power supplied from the external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003 and may improve the operation speed of the electronic system 2000. The DRAM 2004 may be a buffer memory to alleviate the speed difference between the external host and the semiconductor package 2003 that is a data storage space. The DRAM 2004 included in the electronic system 2000 may also operate as a kind of cache memory and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 24. Each of the semiconductor chips 2200 may include metal lines 3210 and channel structures 3220. Each of the semiconductor chips 2200 may include the semiconductor memory device described above with reference to FIGS. 1 to 16.

In some implementations, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method and may be electrically connected to the package upper pads 2130 of the package substrate 2100. In some implementations, in each of the first and second semiconductor packages 2003a and 2003b, the semiconductor chips 2200 may be electrically connected to each other through a connection structure including a through silicon via (TSV) instead of the bonding wire type connection structure 2400.

In some implementations, the main controller 2002 and the semiconductor chips 2200 may be included in one package. In some implementations, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some implementations, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 25.

In an electronic system according to some implementations, each of the semiconductor chips 2200 may include the semiconductor memory device described above with reference to FIGS. 1 to 16. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and the peripheral circuit wiring structure 380 described above with reference to FIGS. 1 to 16. In addition, for example, the cell structure CELL may include the upper insulating layer 100, the common source layer 105, the mold structure MS, the first channel structure CH1, the second channel structure CH2, the first wiring plate 161, the second wiring plate 162, the first vertical gate contact 166, the second vertical gate contact 167, the wiring isolation pattern BSP_1, etc., which are described above using FIGS. 1 to 16.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although certain implementations of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the implementations described above are illustrative and non-limiting in all respects.

What is claimed is:

1. A semiconductor memory device, comprising:
a peripheral circuit structure; and
a cell structure stacked on the peripheral circuit structure, wherein the cell structure includes:
a plurality of gate electrodes stacked and spaced apart from each other in a first direction;
a first channel structure elongated in the first direction and extending through the plurality of gate electrodes, wherein the first channel structure includes a first channel layer and a first vertical gate electrode spaced apart from the first channel layer;
a second channel structure elongated in the first direction and extending through the plurality of gate electrodes, wherein the second channel structure includes a second channel layer and a second vertical gate electrode spaced apart from the second channel layer;
a common source layer connected to the first channel layer and the second channel layer, respectively;
a first wiring plate connected to the first vertical gate electrode;
a second wiring plate connected to the second vertical gate electrode and disposed to be spaced apart from the first wiring plate; and
a wiring isolation pattern disposed between the first wiring plate and the second wiring plate.

2. The semiconductor memory device according to claim 1, wherein the wiring isolation pattern is elongated in a second direction orthogonal to the first direction.

3. The semiconductor memory device according to claim 1, wherein the wiring isolation pattern is elongated in a zigzag pattern in a second direction orthogonal to the first direction.

4. The semiconductor memory device according to claim 1, wherein the cell structure includes a vertical gate contact that extends through the common source layer, wherein the vertical gate contact connects the first vertical gate electrode and the first wiring plate.

5. The semiconductor memory device according to claim 4, wherein
the cell structure includes a common source contact on the common source layer, and
an upper surface of the vertical gate contact and an upper surface of the common source contact are at the same level.

6. The semiconductor memory device according to claim 4, wherein the cell structure includes a contact spacer extending through the common source layer and surrounding the vertical gate contact.

7. The semiconductor memory device according to claim 1, wherein
the cell structure includes a plurality of mold isolation structures elongated in the first direction and separating the plurality of gate electrodes, and
the first channel structure, the second channel structure, and the wiring isolation pattern are between two adjacent mold isolation structures of the plurality of mold isolation structures.

8. The semiconductor memory device according to claim 7, wherein
the plurality of mold isolation structures is elongated in a second direction orthogonal to the first direction, and
the wiring isolation pattern is elongated in the second direction.

9. The semiconductor memory device according to claim 1, wherein
the first channel structure includes a first end connected to the common source layer and a second end opposite to the first end, and
the cell structure includes a bit line contact disposed on the second end of the first channel structure and connected to the first channel layer, and a bit line connected to the bit line contact.

10. The semiconductor memory device according to claim 9, wherein the cell structure includes a cell wiring structure bonded between the bit line and the peripheral circuit structure.

11. The semiconductor memory device according to claim 1, wherein the first channel structure includes:
an insulating liner film between the first vertical gate electrode and the first channel layer; and
an information storage film between the first channel layer and the plurality of gate electrodes.

12. The semiconductor memory device according to claim 11, wherein the insulating liner film covers a lower surface of the first vertical gate electrode.

13. The semiconductor memory device according to claim 1, wherein
the cell structure includes:
a mold isolation structure elongated in the first direction and separating the plurality of gate electrodes; and
a common source wiring layer connected to the common source layer,
the common source wiring layer overlaps the mold isolation structure in the first direction, and
the first wiring plate overlaps the first channel structure in the first direction.

14. The semiconductor memory device according to claim 1, wherein
the first channel structure includes a first end connected to the common source layer and a second end opposite to the first end,
the first channel structure further includes an expanded portion at the first end, and
a width of the first channel layer on the expanded portion is greater than a width of at least a portion of the first channel layer on the plurality of gate electrodes.

15. The semiconductor memory device according to claim 1, wherein the first channel structure and the second channel structure are in the same block.

16. The semiconductor memory device according to claim 1, wherein
the first wiring plate and the second wiring plate are electrically connected to the peripheral circuit structure, and
the peripheral circuit structure provides different signals to each of the first wiring plate and the second wiring plate.

17. A semiconductor memory device, comprising:
a peripheral circuit structure; and
a cell structure stacked on the peripheral circuit structure, wherein the cell structure further includes:
a plurality of gate electrodes stacked and spaced apart from each other in a first direction;
a plurality of mold isolation structures elongated in the first direction and a second direction orthogonal to the first direction and separating the plurality of gate electrodes;
a first channel structure elongated in the first direction and extending through the plurality of gate electrodes, wherein the first channel structure includes a first channel layer and a first vertical gate electrode spaced apart from the first channel layer;
a second channel structure elongated in the first direction and extending through the plurality of gate electrodes, wherein the second channel structure includes a second channel layer and a second vertical gate electrode spaced apart from the second channel layer;
a common source layer connected to the first channel layer and the second channel layer, respectively;
an upper insulating layer on the common source layer;
a common source contact in the upper insulating layer and connected to the common source layer;
a first vertical gate contact extending through the upper insulating layer and the common source layer, wherein the first vertical gate contact is connected to the first vertical gate electrode;
a first wiring plate on the upper insulating layer, connected to the first vertical gate contact, and elongated in the second direction;
a second vertical gate contact extending through the upper insulating layer and the common source layer, wherein the second vertical gate contact is connected to the second vertical gate electrode;
a second wiring plate on the upper insulating layer, connected to the second vertical gate contact, and elongated in the second direction; and
a wiring isolation pattern between the first wiring plate and the second wiring plate.

18. The semiconductor memory device according to claim 17, wherein the first channel structure includes:
an insulating liner film between the first vertical gate electrode and the first channel layer; and
an information storage film between the first channel layer and the plurality of gate electrodes, wherein
the information storage film includes a ferroelectric material.

19. The semiconductor memory device according to claim 17, wherein a width of the first channel structure in the second direction decreases as a distance from the peripheral circuit structure increases.

20. An electronic system comprising:
a main substrate;
a semiconductor memory device on the main substrate, which includes a peripheral circuit structure, and a cell structure stacked on the peripheral circuit structure; and
a controller on the main substrate, which is electrically connected to the semiconductor memory device, wherein
the cell structure includes:
a plurality of gate electrodes stacked and spaced apart from each other in a first direction;
a first channel structure elongated in the first direction and extending through the plurality of gate electrodes, wherein the first channel structure includes a first channel layer and a first vertical gate electrode spaced apart from the first channel layer;
a second channel structure elongated in the first direction and extending through the plurality of gate electrodes, wherein the second channel structure includes a second channel layer and a second vertical gate electrode spaced apart from the second channel layer;
a common source layer connected to the first and second channel layers, respectively, and electrically connected to the controller;
a first wiring plate connected to the first vertical gate electrode;
a second wiring plate connected to the second vertical gate electrode and disposed to be spaced apart from the first wiring plate; and
a wiring isolation pattern between the first wiring plate and the second wiring plate.
